(19) United States
(12) Patent Application Publication
(10) Pub. No.: US 2014/0349011 A1
(43) Pub. Date: Nov. 27, 2014

(54) PROCESSING CHAMBER

(71) Applicant: Oerlikon Advanced Technologies AG, Balzers (LI)

(72) Inventor: Jurgen Weichart, Balzers (LI)

(21) Appl. No.: 14/458,756

(22) Filed: Aug. 13, 2014

Related U.S. Application Data
(62) Division of application No. 12/409,594, filed on Mar. 24, 2009.
(60) Provisional application No. 61/039,185, filed on Mar. 25, 2008.

(51) Int. Cl. C23C 16/458

(52) U.S. Cl. CPC C23C 16/458
USPC 427/248.1; 414/806

(57) ABSTRACT

A process apparatus for treatment of a substrate comprising a load chamber for loading the substrate, a process chamber for processing the substrate, a sealing plane separating the process chamber from the load chamber and means for vertically moving the substrate from the load chamber to the process chamber, and a method for treating the substrate are provided. The load chamber is located in one of the lower and upper portions of the process apparatus, and the process chamber is located in the other of the lower and upper portions of the process apparatus. The process apparatus and method of the present invention will provide easy maintenance and reduced costs by reducing the number of movements for loading the substrate.

### CROSS-REFERENCE TO RELATED APPLICATIONS

This application is a divisional of U.S. patent application Ser. No. 12/409,594, filed Mar. 24, 2009, which claims the benefit of U.S. Provisional Application No. 61/029,185, filed Mar. 25, 2008.

### BACKGROUND OF THE INVENTION

The present invention relates generally to a process chamber for treatment of a substrate such as a semiconductor substrate, and a method of treating the substrate. In particular, the invention relates to a process chamber for treatment of a substrate which will provide easy maintenance and reduced costs by reducing the number of movements for loading the substrate, and a method of treating the substrate.

A prior art semiconductor substrate processing system (“cluster tool”) has a central handler, a transport chamber, and several process chambers. The central handler is located inside the transport chamber, and the process chambers are attached to the transport chamber. The process chambers are separated from the central handler by isolation gate valves.

During normal operation, the handler holds a substrate and laterally moves the substrate above one of the process chambers. Then, the handler vertically moves the substrate down into the designated process chamber by placing the substrate on a set of pins. Thus, at least two movements which are the lateral movement and the vertical movement are required for moving the substrate into the process chamber. In order to lower the cost for loading the substrate, it is necessary to reduce the number of the movements to one. The reduction of the number of the movements will also help reduce the generation of particles during the operation.

The present invention will solve the above-described problems by developing a novel process chamber for treatment of a substrate and a method of treating the substrate which will easy maintenance and reduced costs by reducing the number of movements for loading the substrate.

### SUMMARY OF THE INVENTION

The present invention, in one aspect, concerns, a process apparatus for treatment of a substrate comprising a load chamber for loading the substrate, a process chamber for processing the substrate, a sealing plane separating the process chamber from the load chamber, and means for vertically moving the substrate. The load chamber is located in one of the lower and upper portions of the process apparatus, and the process chamber is located in the other of the lower and upper portions of the process apparatus. The means for vertically moving the substrate moves the substrate from the load chamber to the process chamber.

In a further aspect, the load chamber is located in the lower portion of the process apparatus, and the process chamber is located in the upper portion of the process apparatus.

In a further aspect, the load chamber is located in the upper portion of the process apparatus, and the process chamber is located in the lower portion of the process apparatus.

In a further aspect, the process apparatus comprises first and second openings for loading and unloading the substrate. The first opening is opposed to the second opening.

In a further aspect, the process apparatus is cylindrical and has symmetric interfaces.

In a further aspect, the process chamber performs PVD processing to the substrate.

According to a further aspect, the present invention also provides a method for treating a substrate in a process apparatus having a load chamber for loading the substrate, a process chamber for processing the substrate, a sealing plane separating the process chamber from the load chamber, and means for vertically moving the substrate. The load chamber is located in one of the lower and upper portions of the process apparatus, and the process chamber is located in the other of the lower and upper portions of the process apparatus. The method comprises the steps of loading the substrate to the load chamber; moving vertically the substrate from the load chamber to the process chamber by the vertically moving means through the sealing plane; treating the substrate in the process chamber; and unloading the substrate from the process chamber.

In a further aspect, the load chamber is located in the lower portion of the process apparatus, and the process chamber is located in the upper portion of the process apparatus.

In a further aspect, the load chamber is located in the upper portion of the process apparatus, and the process chamber is located in the lower portion of the process apparatus.

In a further aspect, the process apparatus has first and second openings for loading and unloading the substrate. The first opening is opposed to the second opening.

In a further aspect, the process apparatus is cylindrical and has symmetric interfaces.

In a further aspect, the treating step comprises performing PVD processing to the substrate.

### BRIEF DESCRIPTION OF THE DRAWINGS

The foregoing and other aspects of the present invention will become apparent to those skilled in the art to which the present invention relates upon reading the following description with reference to the accompanying drawings, in which:

FIG. 1 is a top view of a process apparatus according to the present invention.

FIG. 2 is a cross sectional view of one embodiment of a process apparatus according to the present invention.

FIG. 3 is a cross sectional view of another embodiment of a process apparatus according to the present invention.

### DETAILED DESCRIPTION OF EMBODIMENTS OF THE INVENTION

Examples of embodiments that incorporate one or more aspects of the present invention are described and illustrated in the drawings. These illustrated examples are not intended to be a limitation on the present invention. For example, one or more aspects of the present invention can be utilized in other embodiments and even other types of devices. Moreover, certain terminology is used herein for convenience only and is not to be taken as a limitation on the present invention. Still further, in the drawings, the same reference numerals are employed for designating the same elements.

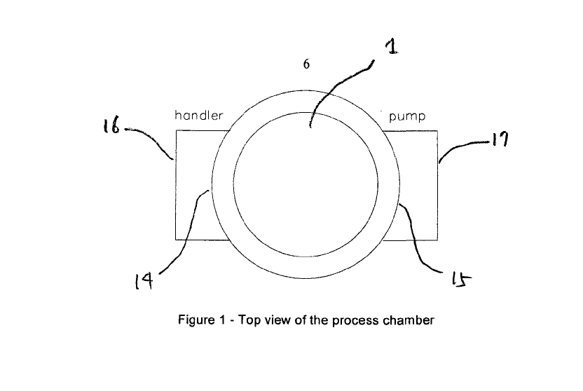

Referring to FIG. 1, there is illustrated a process apparatus 1 for treatment of a substrate according to the present invention. The process apparatus 1 shown in FIG. 1 is cylindrical. The process apparatus 1 has two opposed openings 14, 15. A handler 16 is attached to one opening 14, and a pump 17 is attached to another opening 15.

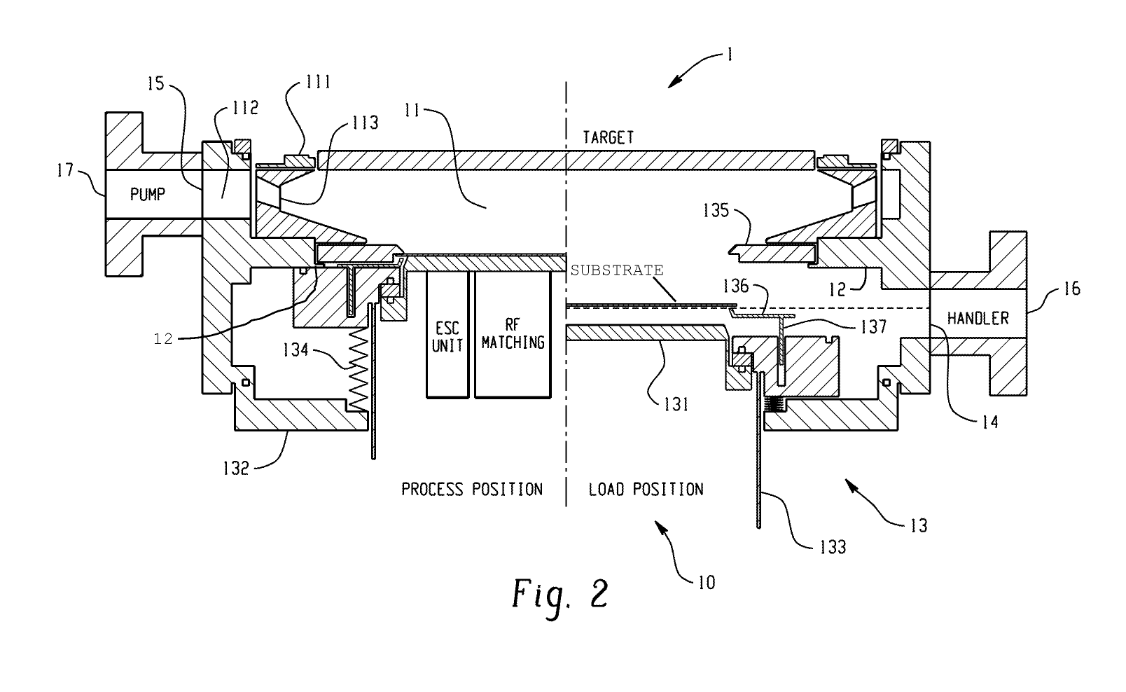

FIG. 2 shows a first embodiment of the process apparatus 1 for treatment of a substrate according to the present invention. As is shown in FIG. 2, the process apparatus 1 has a load chamber 10, a process chamber 11, and a sealing plane 12 defined by a machined edge of the process apparatus 1 on which a clamp ring 135 of a vertically moving means 13 sits in a load position, the vertically moving means 13 being configured to vertically move the substrate from load chamber 10 to the process chamber 11. As is further shown in FIG. 2, when in a process position, an upper surface of a chuck drive system 133 of the vertically moving means 13 contacting the machined edge of the process apparatus 1 may separate the process chamber 11 from the load chamber 10.

The process apparatus 1 is preferably cylindrical and has symmetric interfaces. The process apparatus 1 may be cut from one single piece of aluminum. The load chamber 10 is located in the lower portion of the process apparatus 1. On the other hand, the process chamber 11 is located in the upper portion of the process apparatus 1. As is shown in FIG. 2, the process chamber 11 is closed in the process position at the sealing plane 12.

The process apparatus 1 has two side openings 14, 15. One side opening 14 is opposed to another side opening 15. A handler 16 is located on the lower right side of the process apparatus 1, and attached to the side opening 14. A pump 17 is located on the upper left side of the process apparatus 1, and attached to the side opening 15. The pump 17 may be attached to the process chamber 11 via a gate valve (not shown). The gate valve is especially needed, if the pump 17 is a cryo pump.

The vertically moving means 13 has a chuck 131, a chuck flange 132, the chuck drive system 133, a vacuum sealing bellow 134, the clamp ring 135, a lift ring 136, and at least three lift ring pins 137. The chuck flange 132 carries the chuck 131 from a load position to a process position. The drive system 133 drives the chuck 131. The lift ring 136 may be spring loaded to allow retraction or driven by other means. The lift ring 136, the pins 137 and the chuck 131 may be insulated from the support body, since electric power may be applied to the chuck 131.

The process chamber 11 has a source flange 111, a gas ring 112 and an anode shield 113. A sputter source (not shown) is attached to the source flange 111 which is insulated by a source insulator. The sputter source supplies gas to the process chamber 11 through the gas ring 112. The anode shield 113 provides a counter-electrode to the substrate (such as a substrate, etc.) and protects the inner surfaces of the process chamber 11 from being coated. For maintenance reasons, the anode shield 113 is preferably a single piece shield. The clamp ring 135 is not in contact with the anode shield 113 in order to avoid pressure on the edge of the substrate. In order to do so, the weight of the clamp ring 135 is balanced with the weight of the spring of the lift ring 136.

The following illustrates the operations of treating a substrate in the process apparatus 1 of the present invention.

As is shown in FIG. 2, a substrate is loaded to the lift ring 136 via the handler port of the handler 16 along the illustrated dotted line with the chuck 131 being in a load position. The clamp ring 135 is sitting on a machined edge of the process apparatus 1. As is further shown in FIG. 2, the machined edge of the process apparatus 1 may define the sealing plane 12. For example, as is additionally shown in FIG. 2, a bottom surface of the machined edge of the process apparatus 1 may define the sealing plane 12.

The lift ring 136 is lifted by the at least three pins 137 so that the substrate can be moved in between the lift ring 136 and the clamp ring 135 and lay down on the lift ring 136 by the vertical move of the handling system. Then, after the handling arm is retracted, the chuck 131 is moved up from the load position to the process position. The lift ring pins 137 are moved into their sheath. Then, the clamp ring 135 is moved up from its rest position and holds the substrate in place inside the process chamber 11.

As is shown in FIG. 2, the chuck drive system 133 contacts the machined edge of the process apparatus 1 along the sealing plane 12 when in the process position. For example, as is further shown in FIG. 2, the upper surface of the chuck drive system 133 may contact the machined edge of the process apparatus 1 along the sealing plane 12 when in the process position.

Now, a process gas (e.g., Argon) is introduced from the sputter source via the gas ring 112 to the process chamber 11. The gas ring 112 is protected from being coated by the anode shield 113. The process gas is applied on the substrate. After a sufficient amount of the process gas is applied on the substrate, the supply of the process gas is stopped.

For maintenance, the process chamber 11 is vented in the process position. As is shown in FIG. 2, the load chamber 10 may not be vented since the chuck drive system 133 contacts the machined edge of the process apparatus 1 along the sealing plane 12 when in the process position, which may inhibit the load chamber 10 from being vented. The load chamber 10 is now pumped via the handler 16. The target is lifted or swiveled away to allow access to all parts to be maintained. The target, the anode shield 113, and the clamp ring 135 are usually exchanged. The broken pieces of the substrate may also be removed from the process chamber 11.

Then, the substrate is unloaded from process chamber 11 to the load chamber 10, and discharged via the handler 16.

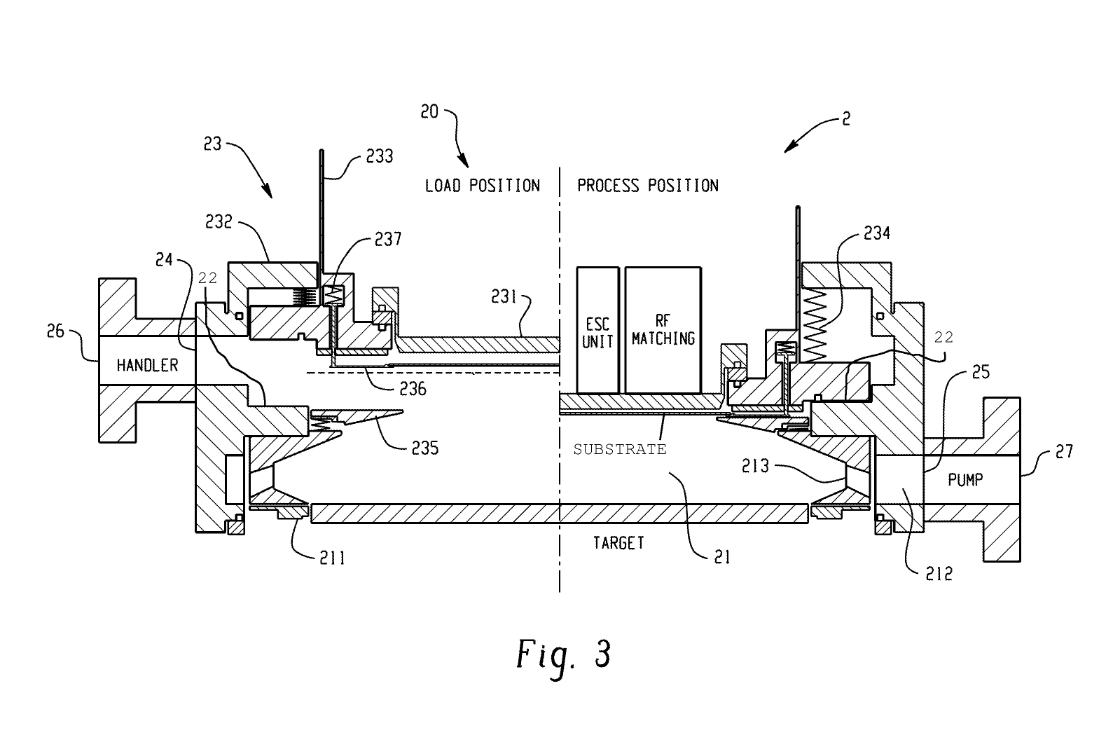

FIG. 3 shows a second embodiment of the process apparatus 2 for treatment of a substrate according to the present invention. As is shown in FIG. 3, the process apparatus 2 has a load chamber 20, a process chamber 21, and a sealing plane 22 defined by a machined edge of the process apparatus 2 adjacent to a position in which a spring loaded clamp ring 235 of a vertically moving means 23 resides, the vertically moving means 23 being configured to move he substrate from load chamber 20 to the process chamber 21. As is further shown in FIG. 3, when in a process position, a lower surface of a chuck drive system 233 of the vertically moving means 23 contacting the machined edge of the process apparatus 2 may separate the process chamber 21 from the load chamber 20.

The process apparatus 2 is also preferably cylindrical and has symmetric interfaces, and may be cut from one single piece of aluminum. Unlike the first embodiment of the process apparatus 1, the load chamber 20 is located in the upper portion of the process apparatus 2 and the process chamber 21 is located in the lower portion of the process apparatus 2. The other parts are the same as the first embodiment, except the handler and the pump are exchanged, the top load chamber 20 is connected to the handler and the chuck flange, and the sputter source is attached to the bottom process chamber 21. As is shown in FIG. 3, the process chamber 21 is closed in the process position at the sealing plane 22.

The process apparatus 2 has two side openings 24, 25. One side opening 24 is opposed to another side opening 25. A handler 26 is located on the upper right side of the process apparatus 2, and attached to the side opening 24. A pump 27 is located on the lower left side of the process apparatus 2, and attached to the side opening 25.

The vertically moving means 23 has a chuck 231, a chuck flange 232, a chuck drive system 233, a vacuum sealing bellow 234, the spring loaded clamp ring 235, a substrate support ring 236, and at least three spring loaded pins 237. The substrate support ring 236 is spring loaded in order not to break the substrate by the applied pressure. The substrate support ring 236 is also insulated to enable the application of electric power to the chuck 231.

The process chamber 21 has a source flange 211, a gas ring 212 and an anode shield 213. A sputter source (not shown) is attached to the source flange 211 which is insulated by a source insulator. The sputter source supplies gas to the process chamber 21.

The following illustrates the operations of treating a substrate in the process apparatus 2 of the present invention.

As is shown in FIG. 3, a substrate is loaded, with the chuck 231 being in a load position, to the substrate support ring 236 via the handler port of the handler 26 along the illustrated dotted line and placed on the substrate support ring 236 by the vertical move of the handling system. As is further shown in FIG. 2, a upper surface of the machined edge of the process apparatus 2 may define the sealing plane 22 as the lower surface of the chuck drive system 233 contacting the machined edge of the process apparatus 2 may separate the process chamber 21 from the load chamber 20.

The substrate support ring 236 is held down by the at least three spring loaded pins 237. Then, after the handling arm is retracted, the chuck 231 is moved down from the load position to the process position. By moving the chuck 231 down, the substrate and the substrate support ring 236 are in contact with the spring loaded clamp ring 235. The spring loaded pins 237 are moved in their sheaths which are also insulated from the grounded support body.

As is shown in FIG. 3, the chuck drive system 233 contacts the machined edge of the process apparatus 2 along the sealing plane 22 when in the process position. For example, as is further shown in FIG. 3, an bottom surface of the chuck drive system 233 may contact the machined edge of the process apparatus 2 along the sealing plane 22 when in the process position.

Now, a process gas (e.g., Argon) is introduced from the sputter source to the process chamber 21. The gas ring 212 is protected from being coated by the anode shield 213. The process gas is applied on the substrate. After a sufficient amount of the process gas is applied on the substrate, the supply of the process gas is stopped.

For maintenance, the process chamber 21 is vented in the process position. As is shown in FIG. 3, the load chamber 20 may not be vented since the chuck drive system 233 contacts the machined edge of the process apparatus 2 along the sealing plane 22 when in the process position, which may inhibit the load chamber 20 from being vented. The load chamber 20 is now pumped via the handler 26. The target, the anode shield 213 and the spring loaded clamp ring 235 can be removed from the bottom.

In this embodiment, the sputter source is attached to the bottom of the process chamber 21. This bottom-up sputter option has advantages for backside metallization, since water flipping is not needed anymore. It is also expected to reduce the particle counts.

Alternatively, instead of placing the sputter source, an etch station, a degas station, a cooling station or a metrology station may be attached to either side of these basic process modules. Stations which have been originally designed for the front application, such as radiation heaters, may be attached to the back side and vice versa.

The invention has been described with respect to various specific embodiments. However, it will be recognized by those skilled in the art that the invention can be practiced with modifications that are within the spirit and scope of the claims that follow.

What is claimed is:

1. A method for treatment of a substrate in a process apparatus (1) with a load chamber (10) for loading the substrate, a process chamber (11) for processing the substrate, and means (13) for vertically moving the substrate from a load position to a process position, the means comprising a chuck (131) with a chuck drive (133), a lift ring (136), and a clamp ring (135), the method comprising:
loading the substrate to the lift ring (136) while the chuck (131) is in the load position and the clamp ring (135) is in a rest position on an edge of the process apparatus (1), the edge of the process apparatus (1) defining a sealing plane (12);
driving the chuck (131), including the lift ring (136) with the substrate, vertically upward from the load position such that the chuck drive (133) contacts the edge of the process apparatus (1) along the sealing plane (12);
moving the clamp ring (135) vertically upward from the rest position to hold the substrate in place inside the process chamber (11) in the process position;
processing the substrate; and
unloading the substrate from the process chamber (11) to the load chamber (10).

2. The method of claim 1, wherein the load chamber (10) is located in a lower portion of the process apparatus (1), and the process chamber (11) is located in an upper portion of the process apparatus (1).

3. The method of claim 1, wherein the processing comprises performing PVD processing to the substrate.

4. The method of claim 1, wherein an upper surface of the chuck drive (133) contacts the edge of the process apparatus (1) along the sealing plane (12).

5. The method of claim 1, wherein the edge of the process apparatus (1) comprises a bottom surface defining the sealing plane (12).

6. The method of claim 5, wherein an upper surface of the chuck drive (133) contacts the bottom surface of the edge of the process apparatus (1) along the sealing plane (12).

7. The method of claim 1, wherein the sealing plane (12) separates the process chamber (11) from the load chamber (10).

8. The method of claim 1, wherein the edge of the process apparatus (1) contacts the chuck drive (133) to separate the process chamber (11) from the load chamber (10).

9. The method of claim 8, wherein a bottom surface of the edge of the process apparatus (1) contacts an upper surface of the chuck drive (133) to separate the process chamber (11) from the load chamber (10).

10. A method for treatment of a substrate in a process apparatus (2) with a load chamber (20) for loading the substrate, a process chamber (21) for processing the substrate, and means (23) for vertically moving the substrate from a load position to a process position, the means comprising a chuck (231) with a chuck drive (233), a substrate support ring (236), and a clamp ring (235), the method comprising:
loading the substrate on the substrate support ring (236) while the chuck (231) is in the load position and the clamp ring (235) is in a rest position adjacent to an edge of the process apparatus (2), the edge of the process apparatus (2) defining a sealing plane (22);
driving the chuck (231), including the substrate support ring (236) with the substrate, vertically downward from the load position to contact the substrate and the substrate support ring (236) with the clamp ring (235) in the process position such that the chuck drive (233) contacts the edge of the process apparatus (2) along the sealing plane (22); and
processing the substrate.

11. The method of claim 10, wherein the load chamber (20) is located in the upper portion of the process apparatus (2), and the process chamber (21) is located in the lower portion of the process apparatus (2).

12. The method of claim 10, wherein the processing comprises performing PVD processing to the substrate.

13. The method of claim 10, wherein a bottom surface of the chuck drive (233) contacts the edge of the process apparatus (2) along the sealing plane (22).

14. The method of claim 10, wherein the edge of the process apparatus (2) comprises an upper surface defining the sealing plane (12).

15. The method of claim 14, wherein a bottom surface of the chuck drive (233) contacts the upper surface of the edge of the process apparatus (2) along the sealing plane (22).

16. The method of claim 10, wherein the sealing plane (22) separates the process chamber (21) from the load chamber (20).

17. The method of claim 10, wherein the edge of the process apparatus (2) contacts the chuck drive (233) to separate the process chamber (21) from the load chamber (20).

18. The method of claim 17, wherein an upper surface of the edge of the process apparatus (2) contacts a bottom surface of the chuck drive (133) to separate the process chamber (21) from the load chamber (20).
